(19) United States
(12) Patent Application Publication
(10) Pub. No.: US 2006/0208747 A1
(43) Pub. Date: Sep. 21, 2006

(54) Test system and connection box therefor

(75) Inventor: Akito Kishida, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/347,346

(22) Filed: Feb. 3, 2006

(30) Foreign Application Priority Data
Mar. 15, 2005 (JP) 2005-073601

(51) Int. Cl. G01R 31/02

(52) U.S. Cl. 324/754

(57) ABSTRACT

A test system comprises a first ground line for connecting a first ground terminal of a tester to a second ground terminal of a prober; a ground plane that covers the bottom surface of the tester and the bottom surface of the prober and is connected by a second ground line to the first ground terminal; and a connection box comprised of a power supply block that supplies the power supply to the tester and the prober each time, receives a first power supply line from the power distribution panel and branches to second and third ground lines for the tester and the prober, and a ground terminal block that receives the third ground line from the power distribution panel and is connected by a fourth ground line to the first ground terminal.

### 1. FIELD OF THE INVENTION

The present invention relates to a measurement technique for semiconductor elements or display panels, and more particularly, to a noise suppression technique when an apparatus such as a prober for handling a measurement object is connected to a tester and measured.

### 2. DISCUSSION OF THE BACKGROUND ART

A panel prober is connected to a panel tester such as an array tester for flat panel displays (FPDs) and takes measurements during the development and manufacture of various display panels, namely, flat panel displays, beginning with liquid crystal displays (LCDs) and organic or inorganic electroluminescent (EL) displays. In particular, and depending on the type of display, since the substrate such as glass is a large object with dimensions exceeding 1 meter on one side, the panel prober must also have a dimension of at least three times the dimension of one side, and securing space for it in a factory becomes difficult.

In the development or manufacture of a semiconductor element such as an integrated circuit (IC), a wafer prober is connected to, for example, an IC tester or a semiconductor parametric tester for evaluating the wafer of the semiconductor element and then takes measurements. Recently, the wafer diameter has increased to 300 mm, and securing the installation space becomes difficult.

Therefore, placing many of these testers and probers at positions separated from the power distribution panel in the factory is considered.

On the other hand, the measurements of the device under test (DUT) installed on these wafers and glass demand high-precision measurements with extremely small currents and voltages due to advances in the fabrication process. To achieve this, noise reduction is necessary.

FIG. 4 shows a diagram for explaining this noise problem. A prober 804 handles, that is, transports and positions, a wafer or glass loaded with a measurement object (not shown) and provides a function for probing specified parts of the measurement object. A tester 802 measures the signals probed via a cable 828 and a test head 826. A power supply line 810 of the tester (hereinafter, simply referred to as the power supply line) and a power supply line 814 of the prober are connected to the terminals of the power supply (PWR) of the power distribution panel 806 of the factory. Similarly, a ground line 812 of the tester and a ground line 816 of the prober are connected to the ground (GND) terminal of the power distribution panel 806. Although not shown, a separate power supply is provided on the power distribution panel and is grounded. In this specification, all of the ground connection lines, or ground lines, explicitly shown in the figure are indicated by dashed lines.

Probing a DUT in the prober 804 is considered here. As indicated by the arrow 830 of the dot-dash line loop, the ground lines 812 and 816 of the tester and the prober form a closed circuit, namely, a ground loop, with a large loop area via the test head 826 and the cable 828 between tester 802, prober 804, and power distribution panel 806. Due to the installation space constraints described above, the lengths of these power supply lines 810 and 814, or ground lines 812 and 816 are often at least 10 meters long. In this case, the radiation of various types of noise in the factory is superimposed or induced in these ground lines or power supply lines, or penetrate the ground loop, and interfere with the measurements in the tester 802.

The tester and various equipment are set up and operate in a mass production line in an environment where an electrical performance evaluation apparatus of semiconductor and display panel elements operates. Moving devices for transferring manufactured goods are also used. Included in these devices are devices with a protected ground installed and fixed, but there are also devices completely separated from the factory power distribution panel such as an unmanned vehicle like an Automated Guided Vehicle (AGV). Generally, many devices without grounding are sources that easily generate common mode noise. From the perspective of noise, even if a protected ground device is used, noise is generated without a satisfactory shielding effect being provided. The measures often applied include: reinforcing the shielding material, using magnetic shielding by permalloy and a sheath mixing ferrite in the power cord to reduce the radiation, and using many ferrite clamps.

A servo motor or a servo amplifier based on feedback control is used to transport the measurement object and to accurately position it within submicron units in the prober or loader used with the measurement apparatus (hereinafter, for simplicity, referred to as a tester in this specification) that handles extremely small voltages and currents.

Usually, if not appropriately used in a servo motor or a servo amplifier, a device generating noise due to high-frequency signals enters a very noisy state because switching is performed by using a rectangular wave with a frequency of several 100 Hz to several 10 kHz. If a tester handling these extremely small voltages and currents is close to the noisy device, the effect of the noise is substantial and the essentially high-precision measurement function cannot be fully utilized.

Furthermore, in a factory, even if the protected ground is provided in the delivery of the power supply, the distance from a ground point to an actual load is sometimes at least 10 meters. In this case, there is concern that the electric potential of the ground line is not stable due to external noise.

In this case, the conductive noise having a relatively low frequency coming from a device generating the noise described above is induced in the ground line. Even if a measure is provided for a device used with the measurement apparatus, the ground of the measurement apparatus vibrates in the common mode caused by the noise generated from surrounding devices lacking this measure.

Consequently, while it is important to reduce the noise level of equipment surrounding the tester and not only the prober, reducing the sensitivity to noise on the tester side that receives the noise is also important.

Unexamined Japanese Patent Publication [Kokai] No. H11[1999]-163,663 shows a tester for extremely small current measurements. Unexamined Japanese Patent Publication [Kokai] No. H6[1994]-53,297 shows a wafer prober. Unexamined Japanese Patent Publication [Kokai] No. 2001-296,547 shows a panel prober.

### SUMMARY OF THE INVENTION

An object of the present invention is to provide a test system for reducing the effect of noise and a connection apparatus for the peripheral power supply and ground, namely, a connection box, when a tester is used with an apparatus, such as a prober, for handling and probing a measurement object in an environment as described above that is easily affected by noise.

The inventors of the present invention analyzed the problems described above, as described below:
(Analysis 1) When each ground line from the tester and prober is connected at a very distant point because the power distribution panel of the power supply is far away in the factory clean room, the ground lines are easily affected by inductive interference from the noise generated by a large number of devices through the power supply lines in the line distribution region.
(Analysis 2) The tester and prober form a spatially wide loop passing through the housings, and noise caused by magnetic fields is induced. High-frequency noise current flows back between the housings because the two ground terminals have mutually different high-frequency potentials and become sources of effects that impact the precision measurement.
(Analysis 3) Furthermore, when the noise frequency bandwidth approaches the measurement sampling timing bandwidth, even if filter processing is applied to the signal, the effect of superimposing the noise component on the measurement is not avoided.
(Analysis 4) Specifically, from an electrical potential point of view for the tester, the inventor figured out a model, where the backward current via the housing, or the enclosure, vibrates the entire prober electrically and is propagated capacitively to a chuck top for placing the device thereon, which causes the measurement noise.
(Analysis 5) Thus, to prevent the current backflow and minimize the radiated electromagnetic energy, a measure for lessening the effect of noise can be effectively applied if a path for back current is designed.

Based on the above analyses, the inventors proposed the following solution strategies.
(Strategy 1) The ground points that ground the housings of the tester and the prober are set as one independent reference point. The ground lines delivered to each housing are shortened and the distribution lines are designed while considering the minimization of the ground loop area while maintaining a low impedance to ground so that the ground points are not affected by inductive noise from the backflowing noise current.
(Strategy 2) Even if the ground lines are affected by inductive noise on the condition that the distance from the power distribution panel to the tester and the prober is long, a design is implemented so that it does not affect on the above-mentioned reference point.
(Strategy 3) In the protected ground design, the design and examination are performed with sufficient attention to preventing electric shocks and short circuits caused by breakdown of insulation.

Based on the above strategies, a test system according to the present invention comprises a prober; a tester that moves in unison with the prober and takes measurements, and also provides a first ground line that connects a first ground terminal of the tester to a second ground terminal of the prober; a ground plane that covers the bottom surface of the tester and the bottom surface of the prober, and is connected by a second ground line to the first ground terminal; and a connection box for supplying the power supply to the tester and the prober, respectively. The connection box comprises a power supply terminal block that receives a first power supply line from the power distribution panel and branches into second and third power supply lines for the tester and the prober. Furthermore, the connection box comprises a ground terminal block that receives a third ground line from the power distribution panel and is connected by a fourth ground line to the first ground terminal.

In a test system of the present invention, the connection box has a fifth ground line, and a fourth ground line of the ground terminal block and ground are connected.

Further, in a test system of the present invention, the connection box has first and second noise cut transformers. The first noise cut transformer is inserted in the second power supply line. The second noise cut transformer is inserted in the third power supply line.

Further, in a test system of the present invention, the connection box has an inductor, a third ground line from a power distribution panel passes through the inductor and connects to the ground terminal block.

Further, in a test system of the present invention, the connection box has first and second earth leakage circuit breakers. The first earth leakage circuit breaker is inserted in the second power supply line. The second earth leakage circuit breaker is inserted in the third power supply line.

Furthermore, in a test system of the present invention, the connection box has first and second earth leakage circuit breakers. The first earth leakage circuit breaker is inserted between the power supply terminal block and the first noise cut transformer of the second power supply line. The second earth leakage circuit breaker is inserted between the power supply terminal block and the second noise cut transformer of the third power supply line.

A test system according to another embodiment of the present invention is a prober, a tester that moves in unison with the prober and takes measurements, and a connection box for supplying the power supply and the ground potential to the tester and the prober, respectively. The connection box comprises a terminal block that receives a first power supply line from the power distribution panel and branches to the second and third power supply lines connected to the tester and the prober, respectively. The terminal block comprises a connection box that receives the first ground line from the power distribution panel and is connected to the second and third connection lines that branch and connect to the tester and the prober, respectively; wherein a first circuit breaker is inserted in the second power supply line, and a second circuit breaker is inserted in the third power supply line.

In a test system according to another embodiment of the present invention, the first and second circuit breakers in the above-mentioned embodiment are molded-case circuit breakers or earth leakage circuit breakers.

A test system according to another embodiment of the present invention comprises a prober; and a tester that moves in unison with the prober and takes measurements, and comprises a first ground terminal that receives a first ground line from the power distribution panel, a second ground line connected between the first ground terminal and the prober, a first power supply terminal that receives a first power supply line from the power distribution panel, and a second power supply line connected through the circuit breaker to the prober.

In the test system according to the present invention, the circuit breaker is a molded-case circuit breaker or an earth leakage circuit breaker.

A connection box for supplying the power supply to the tester and the prober from the power distribution panel. The connection box comprises a power supply terminal block that receives the first power supply line from the power distribution panel, and branches to second and third power supply lines for the tester and the prober. Further, the connection box receives the first ground line from the power distribution panel and provides a second ground line that connects to the tester.

Further, the connection box has a third ground line and connects the second ground line to ground.

Further, the connection box has first and second noise cut transformers; wherein the first noise cut transformer is inserted in the second power supply line, and the second noise cut transformer is inserted in the third power supply line.

Further, the connection box has an inductor, and the first ground line is connected from the power distribution panel through the inductor to the ground terminal block.

Further, the connection box has the first and second earth leakage circuit breakers, wherein the first earth leakage circuit breaker is inserted in the second power supply line, and the second earth leakage circuit breaker is inserted in the third power supply line.

Further, a connection box of the present invention has first and second earth leakage circuit breakers in the above-mentioned embodiment, wherein the first earth leakage circuit breaker is inserted between the power supply terminal block and the first noise cut transformer of the second power supply line, and the second earth leakage circuit breaker is inserted between the power supply terminal block and the second noise cut transformer of the third power supply line.

Further, a connection box of the present invention is a connection box for supplying the power supply to the tester and the prober from the power distribution panel and comprises a terminal block that receives the first power supply line from the power distribution panel and branches to second and third power supply lines connected to the tester and the prober, respectively. The terminal block receives the first ground line from the power distribution panel and is connected to the second and third connection lines that branch and connect to the tester and the prober, respectively. A first circuit breaker is inserted in the second power supply line. A second circuit breaker is inserted in the third power supply line.

Further, a connection box of the present invention, where the first and second circuit breakers in the above-mentioned embodiment are molded-case circuit breakers or earth leakage circuit breakers.

As described above, when an apparatus such as a prober for handling and probing a measurement object is used with a tester and takes measurements, the effect on the measurements can be reduced by using the test system or the connection box according to the present invention. As a result, an electrical measurement and evaluation environment achieving either high speed, high precision, or excellent reproducibility or all of these can be implemented.

### BRIEF DESCRIPTION OF THE DRAWINGS

FIG. 1 is a block diagram for explaining an embodiment of the present invention.

FIG. 2 is a block diagram for explaining another embodiment of the present invention.

FIG. 3 is a block diagram for explaining another embodiment of the present invention. FIG. 4 shows the connections from the power distribution panel of the tester and prober according to a conventional technique.

### DETAILED DESCRIPTION OF THE PREFERRED EMBODIMENT

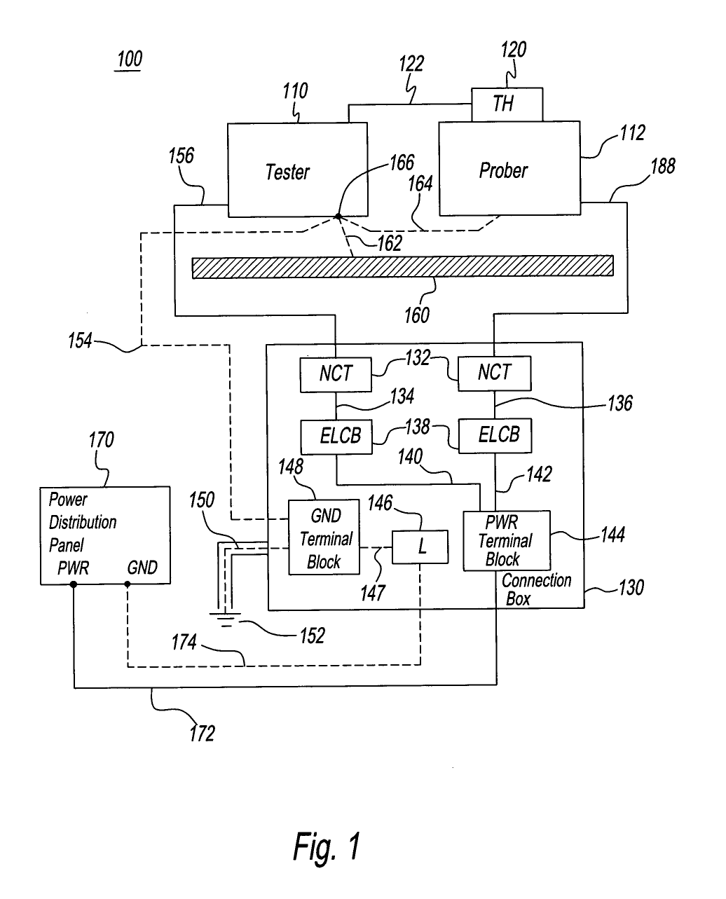

FIG. 1 shows an embodiment according to the present invention. Referring to FIG. 1, a test system 100 comprises a tester 110 for taking measurements, a prober 112 for positioning and probing a measurement object, and a connection box 130 for supplying the power supply and a stable ground potential thereto. A power supply line 172 and a ground line 174 from a power distribution panel 170, which is factory equipment, are connected to the connection box 130 accommodating cabtyre cables.

A test head 120 is connected through a cable 122 to the tester 110. The test head 120 is connected to a prober 112 and receives measurement signals from the prober.

The power supply supplied from the power distribution panel 170 through the power supply line 172 to the connection box 130 is distributed to the power supply lines of the two systems for the tester (140) and for the prober (144) by the power supply (PWR) terminal block 144, passes through earth leakage circuit breakers (ELCB) 138 and cables (134 and 136), is connected to each noise cut transformer (NCT) 132, and is connected to the tester 110 and the prober 112 by respective power supply lines (156 and 158). The ELCB 138 is a circuit breaker having a cut-off function when earth leakage is detected. The noise cut transformer 132 is a transformer that is very effective in cutting off common mode noise in particular and is preferably effective in preventing common mode noise mainly in the 1 MHz bandwidth. In this specification, the same reference numbers are assigned to components having the same function. Although not shown, a power supply and a ground potential are supplied as separate factory equipment to the power distribution panel 170.

The ground potential is connected through an inductor 146 with inductance L in the connection box 130 by the ground line 174 from the power distribution panel 170 to the ground (GND) terminal block 148. Preferably, a toroidal coil is used as the inductor 146 and has an inductance of at least 1 mH in the 10 kHz to 5 MHz bandwidth. The toroidal coil has the smallest possible electrical resistance for direct current and is preferably less than 1 Ω. An inductor wrapped with a thick wire with AWG #10 or thicker is preferred. Therefore, even if noise is superimposed on the ground line 174 from the power distribution panel, noise can have difficulty flowing to the ground side of the tester because the impedance is high for alternating current.

A ground terminal 152 of an external independent ground which satisfies Japanese Industrial Standards (JIS) Class D grounding (equivalent to the previous JIS Class 3 grounding) or equivalent method in individual countries is connected by another ground line 150 to a ground line 147 in a ground terminal block 148. Preferably, the ground line 150 is firmly grounded by the ground line attached to a conduit pipe. Therefore, fluctuations in the ground potential can be prevented.

A ground line 154 connects to the ground line 147 by the ground terminal block 148, and a ground line 154 connects to a ground terminal 166 of the tester 110. Further, the ground terminal 166 is connected through another ground line 164 to a ground terminal of the prober 112. The lengths of the power supply lines 156 and 158 and the ground line 154 reaching the tester 110 or the prober 112 from the connection box 130 are preferably less than 2 meters. In addition, the length of the ground line 164 between the tester 110 and the prober 112 is less than 3 meters.

Further, a ground plane 160 is provided on the floor surfaces covering the bottom surfaces of both the tester 110 and the prober 112. This ground plane 160, for example, is a metal plate such as one or a plurality of aluminum sheets that are closely connected electrically. The back surface of the ground plane 160 is preferably insulated when the installed floor surface is conductive. The ground plane 160 is connected to the ground terminal 166 of the tester 110 by another ground line 162.

In this embodiment, the ground point connected to the ground terminal of the tester housing and the ground terminal of the prober housing are provided on the ground terminal block 148 independently without sharing with another device, and forms a mutual one-point ground at the reference protected ground point 166. There are few fluctuations between the ground potentials.

In this embodiment, the distribution wires (150, 154, 162, 164, 147, and 174) on the load side (tester and prober sides) from the ground terminal block 148 are as thick as possible, equivalent to at least AWG #10 and are preferably made of a material having a low inductance. Each housing from the ground terminal block 148, which is the ground point, is preferably connected by a wire having a length less than 3 m, which is about 1/100^{th} the wavelength of the noise bandwidth, and if possible less than 1 m to 2 m.

Further, the power supply lines (156 and 158) or the ground lines (154, 162 and 164) connecting the connection box 130 to the tester 110 or the prober 112 are preferably constructed from cabtyre cables. Preferably, to prevent inducing noise, the wires are arranged less than about 5 cm from the ground plane or the housing surface. The effect can be greatly increased by also installing a grounded metal duct or ground plane of an aluminum plate, that is, the installed isolation plate 160, and attaching the wires. The ground plane 160 performs the insulation process corresponding to the state of the installation floor surface.

Further, the tester 110 and the prober 112 are close to or connected to both housings (test head 120 and prober 112) in the vicinity of the measurement object and form a ground loop. To prevent an increase in the loop area of the ground loop, both ground lines are arranged to attach to each other and should be arranged to connect in the form of one line (ground lines 154 and 164).

When the tester 110 and the prober 112 are separated by several meters to several tens of meters from the power distribution panel 170, even for one ground point, the long ground line 174 at high frequencies has an impedance, and a noise component is induced in the ground impedance part by the induction from other electrical devices. To suppress the backflow of this noise component to the tester side, an inductor 146, for example, is inserted as the impedance check component in series between ground line 174 and ground line 147.

To stabilize the ground potential, the ground line is drawn into the connection box 130 by the ground line 150 using the conduit pipe from the ground terminal 152 by the third ground as a new clean ground potential. Therefore, a large amount of external ambient noise couples with ground line 150 and flows to the ground terminal 152. The ratio of noise backflowing to the tester side is extremely low. Therefore, a still ground potential with extremely small noise effects is supplied to the tester 110 and the prober 112.

When the captyre cables including the power supply line 172 and the ground line 174 from the power distribution panel 170 to the connection box 130 are extremely long, the noise in the common mode component is mainly superimposed on the power supply line 172. The common mode impedance of the power supply used in the tester is preferably high so that noise does not propagate via the power supply line to the tester 110. However, a typical commercial power supply inserts a capacitor between each power line and ground to reduce the noise of the power supply to satisfy the conducted radiation standard, and the common mode impedance cannot be higher than the value of this capacitor. To lessen the noise in a wide bandwidth, a noise cut transformer is preferably inserted in the ac power supply unit downstream (from the load, that is, from the tester and the prober) of the power supply lines 140 and 142. In the embodiment of FIG. 1, two noise cut transformers 132 are connected in the connection box 130. The preferred noise cut transformer 132 has a check effect in the common mode noise mainly in the 1 MHz bandwidth.

Although not shown, preferably, a primary side shield (a shield on the side of the power distribution panel) of the two noise cut transformers 132 is connected to the ground line 174 upstream of the inductor 146 in order for the noise cut transformers to operate appropriately. A secondary side shield (a shield on the side of tester 110 or prober 112) is connected to the ground line 154.

Further, an earth leakage circuit breaker 138 is installed in the connection box 130 for the tester 110 and the prober 112, respectively. The reason is that there is the need to handle the flows of the earth leakage currents of the total rated currents of the tester 110 and the prober 112 in the inductor 146 when earth leakage current flows in the ground line due to inadequate insulation of the tester 110 or the prober 112 if there are no earth leakage circuit breakers 138. To handle the rare event of a short circuit, an inductor that is larger, heavier, and uneconomical must be provided to withstand large currents. By providing the earth leakage circuit breakers 138, the inductor 146 can have a sufficient margin for the earth leakage current from about 3 mA to 100 mA when stationary. The rated value of the impedance check part can be lowered to the general-purpose use and practical use level (for example, about 10 A maximum). Therefore, the parts can be obtained while satisfying economic considerations.

This embodiment can remove either one or several of the following parts: inductor 146, ground line 150, noise cut transformer 132, and earth leakage circuit breaker 138, depending on the degree of superimposed noise.

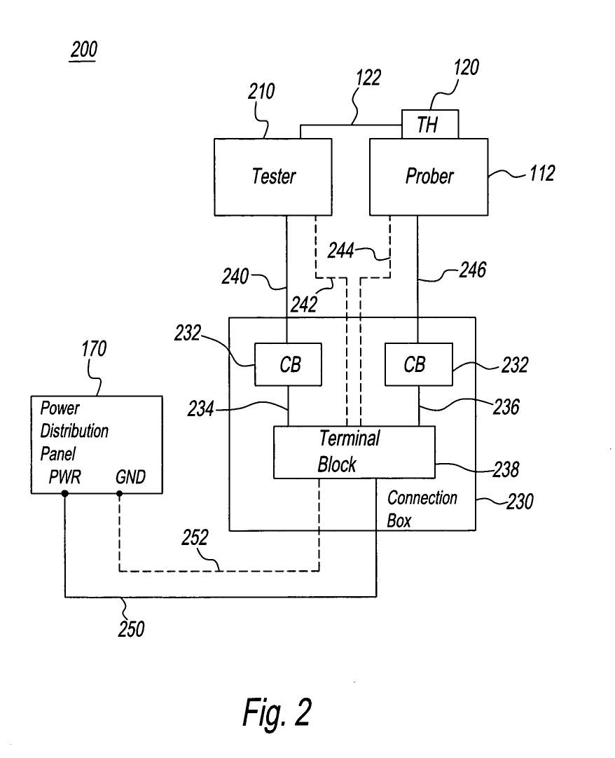

Referring to FIG. 2, another embodiment of the present invention is explained. The test system 200 in FIG. 2 mainly comprises a tester 210 for taking measurements, a prober 112 for positioning and probing a measurement object, and a connection box 230 for supplying the power supply and a stable ground potential thereto. A power supply line 250 and a ground line 252 are connected from the power distribution panel 170, which is factory equipment, to the connection box 230. The components having the same reference numbers as in FIG. 1 are functionally the same objects as in FIG. 1.

The configuration of the tester 210 taking measurements through the cable 122 and the test head 120 by the prober 112 and the functions of the power distribution panel 170 are the same as in FIG. 1.

The power supply supplied from the power distribution panel 170 through the power supply line 250 to the connection box 230 is distributed to the power supply lines of the two systems for the tester (234) and the prober (236) by a terminal block 238, and is connected to the tester 210 and the prober 112 through circuit breakers (CB) 232 and power supply cables (240 and 246), respectively. A molded-case circuit breaker (MCCB) or an earth leakage circuit breaker (ELCB) can be used as the circuit breaker 232.

The ground potential supplied from the power distribution panel 170 to the terminal block 238 by a ground line 252 is distributed by the terminal block 238 and is connected to the tester 210 and the prober 112 by the ground lines 242 and 244, respectively.

The lengths of the ground lines from the connection box 230 to the tester 210 or the prober 112 are preferably 2 meters or less.

This embodiment is preferably applied when a low noise level is superimposed on the power supply line 250 and the ground line 252 compared to the embodiment in FIG. 1. The structure of the connection box 230 is simplified. The ground plane is removed. And the connections of the ground lines to the tester 210 and the prober 112 are changed.

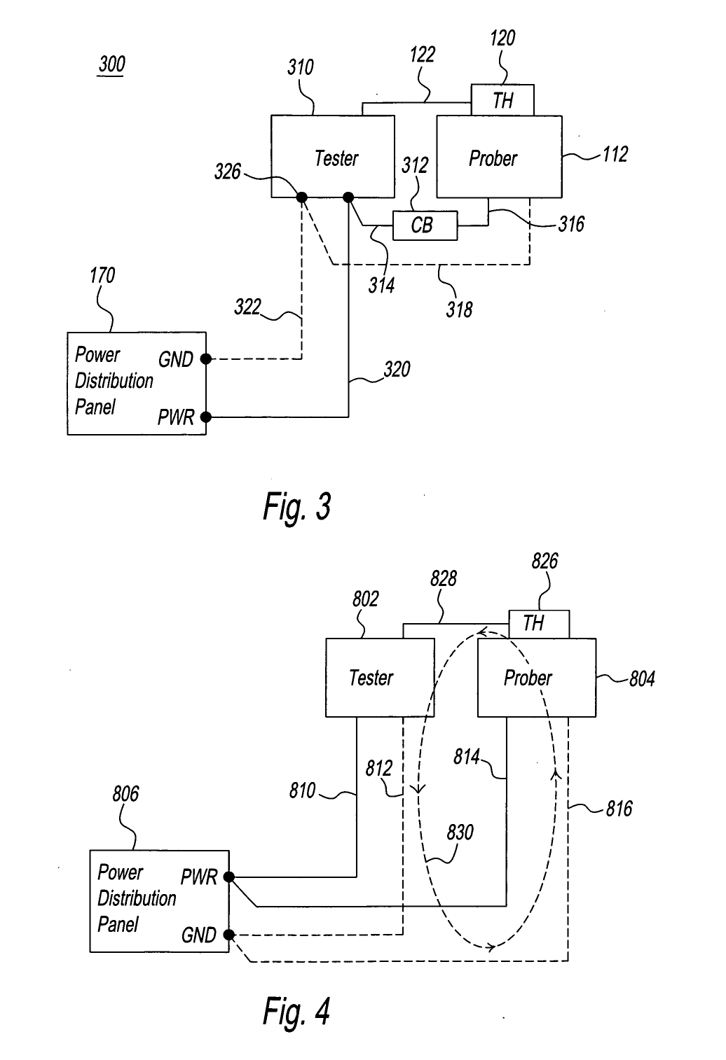

Referring to FIG. 3, another embodiment according to the present invention is explained. The test system 300 in FIG. 3 mainly comprises a tester 310 for taking measurements and a prober 112 for positioning and probing the measurement object. A power supply line 320 and a ground line 322 are connected from the power distribution panel 170, which is factory equipment, to the tester 310. The components having the same reference numbers as in FIG. 1 are functionally the same objects as in FIG. 1. The configuration where the tester 310 takes measurements by the prober 112 through a cable 122 and a test head 120 and the functions of the power distribution panel 170 are the same as FIG. 1.

The power supply connected from the power distribution panel 170 through the power supply 320 to the power supply terminal 324 of the tester 310 is connected from the power supply terminal 324 through a circuit breaker (CB) by another power supply line 314 and another power supply line 316 to the prober 112.

The ground potential connected from the power distribution panel 170 through the ground line 322 to the ground terminal 326 of the tester 310 is connected from the ground terminal 326 through another ground line 318 to the prober 112. A molded-case circuit breaker (MCCB) or an earth leakage circuit breaker (ELCB) can be used as the circuit breaker 312. The length of the ground line 318 is preferably less than 3 meters.

The power supply and the ground potential are supplied as separate factory equipment to the power distribution panel 170 as in FIG. 1.

This embodiment can tie together two cables in the power supply terminal 324 and ground terminal 326 of the tester 310, always allow connecting in one line, and is suited to the case where noise having the same level as in the embodiment in FIG. 2 is superimposed on the power supply line 320 and the ground line 322. This is believed to eliminate the connection box, change the connections of the power supply lines and the ground lines of the tester 310 and the prober 112, and reduce the loop area of the ground loop by connecting in a single line. By providing a circuit breaker 312, a wire material with appropriate specifications, that is, a material that is easily obtained and economical, can be adopted for the power supply line 316. Another embodiment that eliminates the circuit breaker 312 is also possible.

An embodiment of the present invention was explained above with a tester and a prober as the example. Various testers beginning with an IC tester, semiconductor parametric tester, and FPD array tester are included as such testers. Various devices for positioning and probing the measurement object beginning with a wafer prober and a panel prober are included as the prober. Various loaders that take an unfinished product of a semiconductor or a display panel from the storage container and are combined in the tester may be used to replace the prober. Further, the present invention can be applied when other apparatus for handling the measurement object and a tester are combined and used. Various embodiments are not shown, and various modifications within the scope of the claims of the present invention can be implemented and are easily understood by a person skilled in the art.

What is claimed is:

1. A test system which comprises:
a prober;
a tester that moves in unison with said prober and takes measurements, wherein the tester provides a first ground line for connecting a first ground terminal of said tester to a second ground terminal of said prober;
a ground plane that covers the bottom surface of said tester and the bottom surface of said prober, and is connected by a second ground line to said first ground terminal; and
a connection box for supplying the power supply to each of said tester and said prober, wherein said connection box comprises a power supply terminal block that receives a first power supply line from the power distribution panel and branches into second and third power supply lines for said tester and said prober, and said connection box comprises a ground terminal block that receives a third ground line from the power distribution panel and is connected to said first ground terminal by a fourth ground line.

2. The test system of claim 1, wherein said connection box has a fifth ground line, and said fourth ground line of said ground terminal block and ground are connected by said fifth ground line.

3. The test system of claim 1, wherein said connection box has first and second noise cut transformers; said first noise cut transformer is inserted in said second power supply line; and said second noise cut transformer is inserted in said third power supply line.

4. The test system according to claim 1, wherein said connection box has an inductor; and a third ground line from said power distribution panel passes through said inductor and connects to said ground terminal block.

5. The test system according to claim 1, wherein said connection box has first and second earth leakage circuit breakers; said first earth leakage circuit breaker is inserted in said second power supply line; and said second earth leakage circuit breaker is inserted in said third power supply line.

6. The test system of claim 3, wherein-said connection box has first and second earth leakage circuit breakers; said first earth leakage circuit breaker is inserted between said power supply terminal block and said first noise cut transformer of said second power supply line; and said second earth leakage circuit breaker is inserted between said power supply terminal block and said second noise cut transformer of said third power supply line.

7. A test system which comprises:
a prober;
a tester that moves in unison with said prober and takes measurements; and
a connection box for supplying the power supply and the ground potential to said tester and said prober, respectively, wherein said connection box comprises a terminal block that receives a first power supply line from the power distribution panel and branches to second and third power supply lines connected to said tester and said prober, respectively; said terminal block receives a first ground line from the power distribution panel and is connected to second and third connection lines that branch and connect to said tester and said prober, respectively; a first circuit breaker is inserted in said second power supply line; and a second circuit breaker is inserted in said third power supply line.

8. The test system of claim 7, wherein said first and second circuit breakers are molded-case circuit breakers or earth leakage circuit breakers.

9. A test system which comprises:
a prober; and
a tester that moves in unison with said prober and takes measurements, wherein said tester provides a first ground terminal, and a first ground line from the power distribution panel is received by said first ground terminal, and a second ground line is connected between said first ground terminal and said prober; said tester provides a first power supply terminal, and receives a first power supply line from said power distribution panel by said first power supply terminal; and a second power supply line is connected through the circuit breaker between said first power supply terminal and said prober.

10. The test system of claim 9, wherein said circuit breaker is a molded-case circuit breaker or an earth leakage circuit breaker.

11. A connection box for supplying the power supply to the tester and the prober from the power distribution panel, wherein said connection box provides a power supply terminal block that receives a first power supply line from said power distribution panel, and branches to second and third power supply lines for said tester and said prober; and said connection box comprises a second ground line that receives a first ground line from the power distribution panel and is connected to said tester.

12. The connection box of claim 11, wherein said connection box has a third ground line and connects said second ground line to ground.

13. The connection box of claim 11, wherein said connection box has first and second noise cut transformers; said first noise cut transformer is inserted in said second power supply line; and said second noise cut transformer is inserted in said third power supply line.

14. The connection box of claim 11, wherein said connection box has an inductor; and a first ground line from said power distribution panel passes through said inductor and is connected to said ground terminal block.

15. The connection box of claim 11, wherein said connection box has first and second earth leakage circuit breakers; said first earth leakage circuit breaker is inserted in said second power supply line; and said second earth leakage circuit breaker is inserted in said third power supply line.

16. The connection box of claim 13, wherein said connection box has first and second earth leakage circuit breakers; said first earth leakage circuit breaker is inserted between said power supply terminal block and said first noise cut transformer of said second power supply line; and said second earth leakage circuit breaker is inserted between said power supply terminal block and said second noise cut transformer of said third power supply line.

17. A connection box for supplying the power supply to the tester and the prober from the power distribution panel, wherein said connection box comprises a terminal block that receives a first power supply line from the power distribution panel and branches to second and third power supply lines connected to the tester and the prober, respectively; and said terminal block receives a first ground line from the power distribution panel and is connected to second and third connection lines that branch and connect to said tester and said prober, respectively; a first circuit breaker is inserted in said second power supply line; and a second circuit breaker is inserted in said third power supply line.

18. The connection box of claim 17, wherein said first and second circuit breakers are molded-case circuit breakers or earth leakage circuit breakers.
